(19) United States
(12) Patent Application Publication
(10) Pub. No.: US 2004/0048203 A1
(43) Pub. Date: Mar. 11, 2004

(54) Method of manufacturing a semiconductor device for high speed operation and low power consumption

(75) Inventors: Takeshi Furusawa, Hino (JP); Shuntaro Machida, Kokubunji (JP); Daisuke Ryuzaki, Kokubunji (JP)

Correspondence Address: Stanley P. Fisher, Reed Smith LLP, Suite 1400, 3110 Fairview Park Drive, Falls Church, VA, 22042-4503, US

(73) Assignee: Hitachi, Ltd.

(21) Appl. No.: 10/447,148

(22) Filed: May 29, 2003

(30) Foreign Application Priority Data
Sep. 10, 2002 (JP) P2002-264600

(51) Int. Cl. G03F 7/16; G03F 7/20; G03F 7/40; C23C 14/34

(52) U.S. Cl. 430/314; 430/316; 430/317; 204/192.22

(57) ABSTRACT

A method of manufacturing a semiconductor device is provided. In one example, the method includes fabricating holes and/or trenches in organosiloxane insulating film without damaging the film by ashing and without causing a problem of shape deterioration or obstacles. The method comprising forming a second insulating film and a inorganic thin film soluble to a dissolving solution on an organosiloxane insulating film, fabricating the organosiloxane insulating film using the inorganic thin film as a hard mask, and removing the hard mask after fabrication by a dissolving solution.

### COPYRIGHT NOTICE

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### BACKGROUND OF THE INVENTION

1. Field of the Invention

The present invention generally relates to a method of manufacturing a semiconductor device and, more particularly, to a method of manufacturing a semiconductor device for high speed operation and/or low power consumption.

2. Discussion of Background

Along with refinement of semiconductor devices, the parasitic capacitance of Cu wirings is about equal with the input/output capacitance of a transistor itself, which restricts the device operation. In view of the above, introduction of insulating films of lower relative dielectric constant than that of conventional silicon oxide (relative dielectric constant of 4 or lower) have been studied vigorously.

Organosiloxane insulating films are mainly studied for low dielectric constant films. An organosiloxane insulating film mainly comprises Si—R bond (R: organic group) and Si—O—Si bond as main components. It is formed by a chemical vapor deposition process or a spin coating method. CH₃ of excellent heat resistance is generally used for R. Si—H or Si—C—Si may sometimes be contained as other ingredient. The relative dielectric constant of organosiloxane insulating film is usually about 2.8 to 3.3, and the relative dielectric-constant can be reduced to 2.5 or less by making the film porous.

A damascene method is generally adopted as a Cu wiring forming method. The damascene method comprises forming a trench or hole pattern corresponding to wirings or via holes to an insulating film at first and then burying a barrier metal and Cu into the pattern and, further, removing unnecessary barrier metal and Cu out of the pattern by chemical mechanical polishing. Among the damascene methods, a method of burying Cu simultaneously into both of wiring and via hole patterns is referred to as a dual damascene method.

For applying the organosiloxane insulating film to Cu wirings, fabrication of the trench or hole pattern is necessary. The fabrication method of the trench/hole pattern to the organosiloxane insulating film includes the following methods. The first is a resist mask method of fabricating the trench/hole pattern to an organosiloxane insulating film directly using a resist pattern as a mask. The second is a hard mask method of once transferring a resist pattern to a hard mask, removing the resist and then fabricating the trench/hole pattern to the underlying organosiloxane insulating film by using the hard mask.

For the hard mask, silicon oxide, silicon nitride, silicon oxynitride, silicon carbide, silicon carbonitride or a layered film thereof is generally studied. Further, the following patent literature 1 discloses a method of using aluminum oxide as a hard mask and the following patent literature 2 discloses a method of using films of metals such as Al, Ta or Ti or films of oxides, nitrides or carbides thereof as a hard mask Further, it is also disclosed a method of forming a soluble thin film as the underlayer for the hard mask, fabricating trench/hole pattern to an organosiloxane insulating film by using the handmask and then dissolving the soluble thin film by using a dissolving solution and removing the hard mask by lift-off (for example, referred to patent literature 3). The hard mask include, for example, Si, W, Al, Ni, Ti, Ca and aluminum oxide, and the soluble thin film can include tungsten oxide, aluminum oxide and the like.

Patent literature 1: JP-A No. 2000-208444

Patent literature 2: JP-A No. 2000-150463

Patent literature 3: JP-A No. 2000-15479

The resist mask method involves the following two problems.

The first problem is degradation of an organosiloxane insulating film during resist removal. In the resist mask method, organic components in the organosiloxane insulating film are decomposed by an asher treatment (oxygen plasma treatment) for removing the resist. As a result, this causes increase in the relative dielectric constant and/or increase in the leakage current. In a case of the organosiloxane insulating film with a relative dielectric constant of about 2.8 to 3.3, oxidation damage can be reduced by lowering the pressure of the asher treatment or by using an ammonia plasma treatment.

However, in a porous film with a relative dielectric constant of 2.5 or less, since plasma tend to intrude to the inside of the film, damages are not enough reduced.

The second problem is a dry etching resistance of the resist for ArF lithography used 90 nm node technology and beyond. Generally, the resist materials used in ArF lithography have poor resistance against fluoric plasma resistance. By the way, in the resist mask method, the resist is exposed to fluoric plasma during etching of the organosiloxane insulating film. As a result, the shape of the resist is deteriorated and the deteriorated shape is transferred to the organosiloxane insulating film.

On the other hand, in the hard mask method, since the organosiloxane insulating film is not exposed to the asher treatment, there is no problem in view of damages. Different problems are caused depending on the hard mask materials. In the hard mask materials studied gene-rally (such as silicon oxide, silicon nitride, silicon oxynitride, silicon carbide and silicon carbonitride), the dry etching selectivity of the organosiloxane insulating film to the hard mask is about 2 to 6 at the highest and fabrication at high accuracy can not be conducted.

In the metal hard mask, the selectivity ratio is sufficiently high. The first problem is that the underlying layer is invisible due to the reflection at the metal surface and alignment can not be conducted in the lithography. The second problem is that the pattern shape is deteriorated upon removing the metal hard mask after patterning for preventing short-circuit between adjacent wirings.

The selectivity is sufficiently high also in the hard masks of metal oxides and nitrides. The first problem is that metal oxides of high dielectric constant have to be removed in order to lower the wirings capacitance. The hard mask is not removed in patent literature 1, while a concrete method of removing is not disclosed in patent literature 2. While patent literature 3 discloses a method of removing the hard mask by lift-off, since hard mask itself is not dissolved by lift-off, residues tend to be deposited again as obstacles, which is not practical.

The second problem is the selectivity during hard mask patterning. Since metal oxides and the like are less etched, a high bias is necessary for etching. As disclosed in patent literature 1 and patent literature 2, when the organosiloxane insulating film is used for the underlying of the hard mask, the selectivity ratio of the metal oxides is 0.5 or less. Particularly, the selectivity ratio is low in the porous material and deep recess is formed by over etching for hard mask patterning. The problem of damages, like the case of using the resist mask, also occurs during asher treatment for removal of resist.

The present invention intends to provide a process for fabrication of holes and trenches at high accuracy for an organosiloxane insulating film without causing damages to the organosiloxane insulating film by an asher treatment and without causing problems of shape deterioration and obstacles.

### SUMMARY OF THE INVENTION

Subject described above can be solved by forming a second insulating film on an organosiloxane insulating film on which a soluble inorganic film soluble to a dissolving solution is formed and fabricating trench/hole pattern to the organosiloxane insulating film using the soluble thin film as a hard mask. After patterning the organosiloxane insulating film, the hard mask is removed by the dissolving solution without causing deterioration of the shape.

The soluble inorganic thin film can provide a sufficiently high selectivity to the organosiloxane insulating film so long as the thin film is a metal oxide film, an oxynitride film or nitride film. Among them, aluminum oxide and aluminum oxynitride are preferred. While they can be formed by a spin coating method, it is desirable to form them by a sputtering method or a reactive sputtering method in order to obtain higher selectivity ratio. Furthermore, since aluminum oxynitride has a UV-ray absorbing characteristic, it also has an advantage capable of omitting the anti-reflection coating in the lithographic step by controlling the film thickness.

Aluminum oxide and aluminum oxynitride are soluble to a solution containing fluorine such as diluted hydrofluoric acid and ammonia fluoride. For attaining a practical dissolving (removing) rate without giving undesired effects on the underlying Cu or organosiloxane insulating film, the fluorine concentration in the dissolving solution is preferably at 0.0005% or more and 0.5% or less.

It is desirable that the second insulating film is one of silicon oxide, silicon nitride, silicon oxynitride, silicon carbide or silicon carbonitride which has an etching selectivity during hard mask patterning higher than that of the organosiloxane insulating film. Among them, silicon oxide has a highest selectivity. On the other hand, silicon carbide has highest adhesion with the underlying organosiloxane insulating film. Accordingly, a layered film in which silicon oxide is formed on silicon carbide is further preferred.

Further, in a case where Cu wirings or via holes are exposed on the underlying layer upon forming the organosiloxane insulating film, it is preferred to form one of silicon nitride, silicon oxynitride, silicon carbide or silicon carbonitride having Cu diffusion barrier property and then forming an organosiloxane insulating film in order that Cu and organosiloxane insulating film are not in contact directly with each other to result in the problem of reliability.

Further, for the fabrication of the hard mask, it is preferred to use at least a chlorine-containing gas such as Cl₂ or BCl₃ for the patterning of the hard mask. Particularly, since a resist for ArF lithography has high chlorine plasma resistance, it can suppress the deterioration of the resist shape.

Further, the hard mask is removed preferably before burying a metal such as Cu or the like into a pattern. This is because steps are formed when metal burying and chemical mechanical polishing (CMP) are conducted in a state where the hard mask is present and then the hard mask is removed by the dissolving solution. Further, while it is possible to remove the hard mask by CMP itself, steps called as dishing or erosion is formed due to increase of the CMP time.

The invention encompasses other embodiments of a method and an apparatus, which are configured as set forth above and with other features and alternatives.

### BRIEF DESCRIPTION OF THE DRAWINGS

The present invention will be readily understood by the following detailed description in conjunction with the accompanying drawings. To facilitate this description, like reference numerals designate like structural elements.

FIG. 1 is an explanatory view of a gate-upper layer insulating film and a contact formed on a semiconductor substrate formed with a transistor, in accordance with an embodiment of the present invention;

FIG. 2 is another explanatory view of a gate-upper layer insulating film and a contact formed on a semiconductor substrate formed with a transistor, in accordance with an embodiment of the present invention;

FIG. 3 is an explanatory view of an anti-reflection coating and an ArF resist formed and a lower layer wiring pattern formed by ArF lithography, in accordance with and embodiment of the present invention;

FIG. 4 is an explanatory view of the anti-reflection coating and the aluminum oxide patterned by using the resist as a mask, in accordance with and embodiment of the present invention;

FIG. 5 is an explanatory view of ashing applied by oxygen plasma to remove the anti-reflection coating and the ArF resist, in accordance with and embodiment of the present invention;

FIG. 6 is an explanatory view of silicon oxide 113 and the organosiloxane insulating film 112 patterned using the aluminum oxide as a hard mask, in accordance with embodiment of the present invention;

FIG. 7 is an explanatory view of post cleaning conducted using a commercially available acidic cleaning solution containing NH₄F to dissolve and remove the aluminum oxide together with etching residues, in accordance with an embodiment of the present invention;

FIG. 8 is an explanatory view of barrier metal 143 and a Cu 144 formed in the pattern by a damascene method comprising a directional sputtering method, a plating method and a CMP method in combination to form underlayer wirings, in accordance with an embodiment of the present invention;

FIG. 9 shows the upper plan view in the state of FIG. 8, in accordance with one embodiment of the present invention;

FIG. 10 is an explanatory view of a silicon carbonitride of 20 nm thickness as a barrier insulating film, an organosiloxane insulating film of 250 nm thickness and a silicon oxide film of 80 nm thickness formed by a plasma CVD method, and an aluminum oxide film of 30 nm thickness formed by a reactive sputtering method, in accordance with one embodiment of the present invention;

FIG. 11 shows a view of a barrier metal and a Cu formed in the pattern by a damascene method for via connection, in accordance with one embodiment of the present invention;

FIG. 12 shows another view of a barrier metal and a Cu formed in the pattern by a damascene method for via connection, in accordance with one embodiment of the present invention;

FIG. 13 shows another view of a barrier metal and a Cu formed in the pattern by a damascene method for via connection, in accordance with one embodiment of the present invention;

FIG. 14 shows another view of a barrier metal and a Cu formed in the pattern by a damascene method for via connection, in accordance with one embodiment of the present invention;

FIG. 15 shows another view of a barrier metal and a Cu formed in the pattern by a damascene method for via connection, in accordance with one embodiment of the present invention;

FIG. 16 shows an upper plan view in the state of FIG. 15, in accordance with one embodiment of the present invention;

FIG. 17 is an explanatory view of a barrier metal and Cu formed in the pattern by a damascene method to form upper layer wirings, in accordance with one embodiment of the present invention;

FIG. 18 shows an upper plan view in the state of FIG. 17;

FIG. 19 shows a dissolution rate of aluminum oxide into a diluted solution of hydrofluoric acid, in accordance with one embodiment of the present invention;

FIG. 20 shows an anti-reflection coating and an ArF resist formed and a via hole pattern 231 formed by ArF lithography, in accordance with one embodiment of the present invention;

FIG. 21 shows the anti-reflection coating and the aluminum oxide patterned by using the resist as a mask, in accordance with one embodiment of the present invention;

FIG. 22 shows ashing applied by oxygen plasma to remove the anti-reflection coating and the ArF resist, in accordance with one embodiment of the present invention;

FIG. 23 shows silicon oxide and a portion of the organosiloxane insulating film patterned by using the aluminum oxide as a hard mask, in accordance with one embodiment of the present invention;

FIG. 24 shows an anti-reflection coating and an ArF resist formed and an upper layer wiring pattern formed by ArF lithography, in accordance with one embodiment of the present invention;

FIG. 25 shows the anti-reflection coating and the aluminum oxide patterned using a resist as a mask, in accordance with one embodiment of the present invention;

FIG. 26 shows ashing applied to remove the antireflection coating and the ArF resist, in accordance with one embodiment of the present invention;

FIG. 27 shows the silicon oxide, the organosiloxane insulating film and the silicon carbonitride film patterned by using the aluminum oxide as a hard mask, in accordance with one embodiment of the present invention;

FIG. 28 shows post cleaning conducted using a commercially available an acidic cleaning solution containing NH₄F to dissolve and remove aluminum oxide together with etching residues, in accordance with one embodiment of the present invention;

FIG. 29 shows barrier metal and Cu formed in the pattern by a damascene method comprising a directional sputtering method, a plating method and a CMP method in combination to form upper layer wirings and via connections, in accordance with one embodiment of the present invention;

FIG. 30 shows an anti-reflection coating and an ArF resist formed and an upper layer pattern formed by ArF lithography, in accordance with one embodiment of the present invention;

FIG. 31 shows the anti-reflection coating 224 and the aluminum oxide 221 patterned by using the resist 225 as a mask, in accordance with one embodiment of the present invention;

FIG. 32 shows ashing applied by oxygen plasma to remove the anti-reflection coating and the ArF resist, in accordance with one embodiment of the present invention;

FIG. 33 shows an anti-reflection coating and an ArF resist formed and a via hole pattern formed by ArF lithography, in accordance with one embodiment of the present invention;

FIG. 34 shows the anti-reflection coating, silicon oxide and a portion of the organosiloxane patterned using a resist as a mask, in accordance with one embodiment of the present invention;

FIG. 35 shows ashing applied to remove the antireflection coating and the ArF resist, in accordance with one embodiment of the present invention;

FIG. 36 shows the silicon oxide, the organosiloxane insulating film and the silicon carbonitride film patterned by using the aluminum oxide as a hard mask, in accordance with one embodiment of the present invention;

FIG. 37 shows post cleaning conducted using a commercially available acidic cleaning solution containing NH₄F to dissolve and remove the aluminum oxide together with etching residues, in accordance with one embodiment of the present invention;

FIG. 38 shows barrier metal and a Cu formed in the pattern by a damascene method comprising a directional sputtering method, a plating method and a CMP method in combination to form upper layer wirings and via connections, in accordance with one embodiment of the present invention;

FIG. 39 shows an anti-refraction film and ArF resist formed and a via hole pattern formed by ArF lithography, in accordance with one embodiment of the present invention;

FIG. 40 shows the anti-reflection coating and the sacrificial film patterned by using the resist as a mask, in accordance with one embodiment of the present invention; and

FIG. 41 shows the resist and the anti-reflection coating removed by ashing, in accordance with one embodiment of the present invention.

### DESCRIPTION OF THE PREFERRED EMBODIMENTS

An invention for a method of manufacturing a semiconductor device is disclosed. Numerous specific details' are set forth in order to provide a thorough understanding of the present invention. It will be understood, however, to one skilled in the art, that the present invention may be practiced without some or all of these specific details.

<Embodiment 1>

Cu multi-level wirings for a semiconductor device were prepared by a single damascene method.

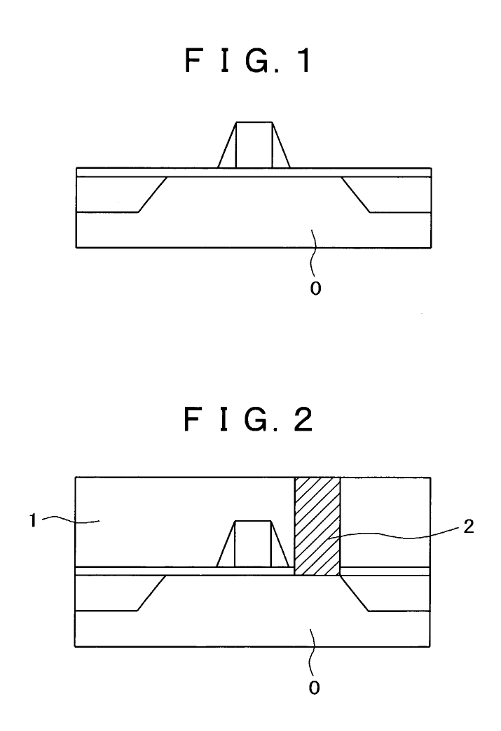

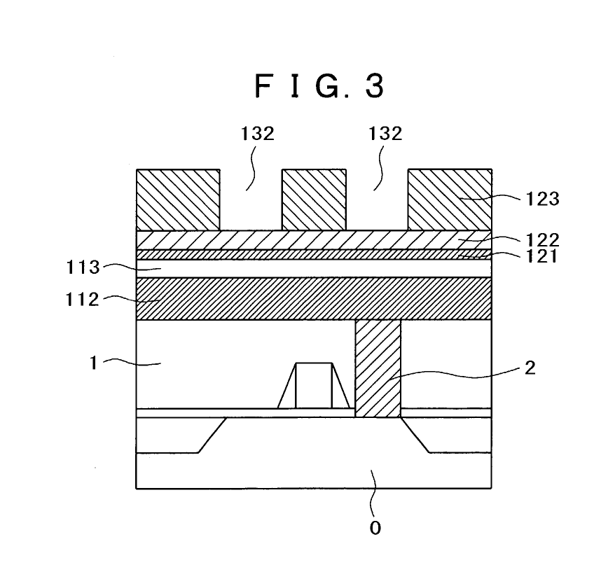

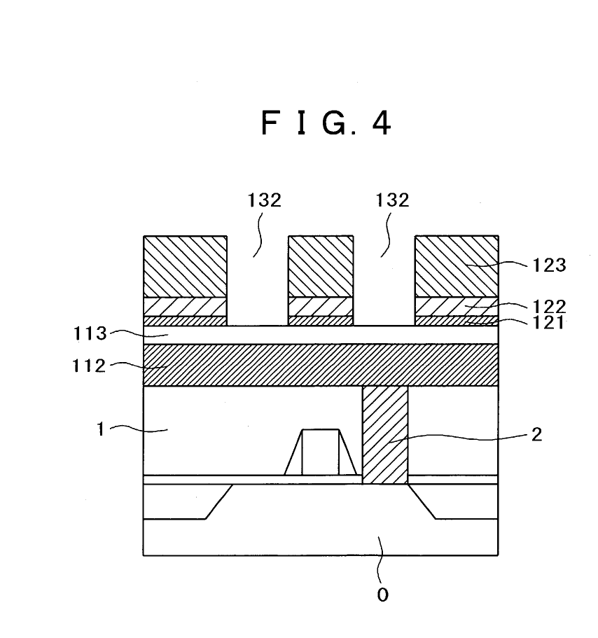

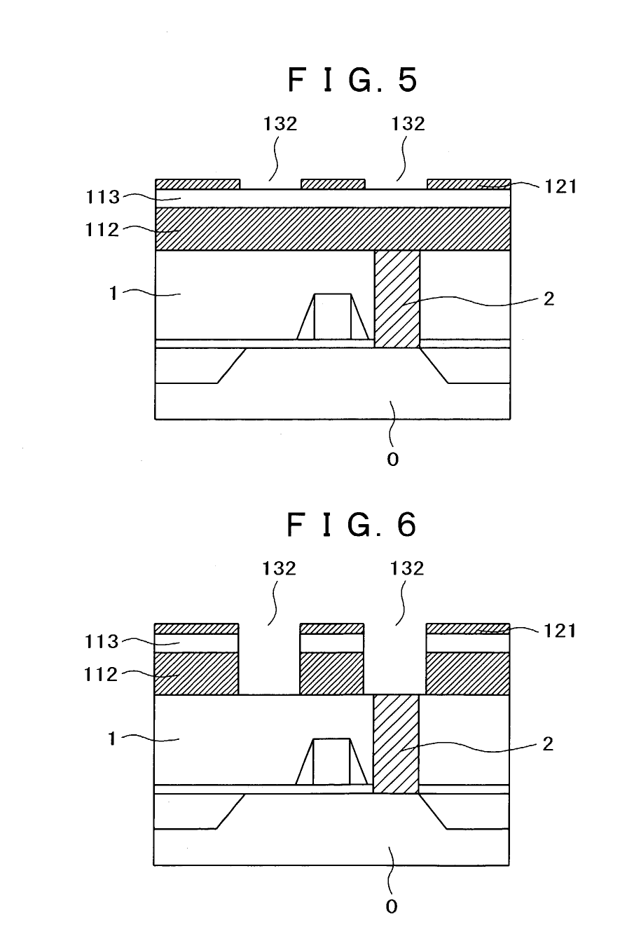

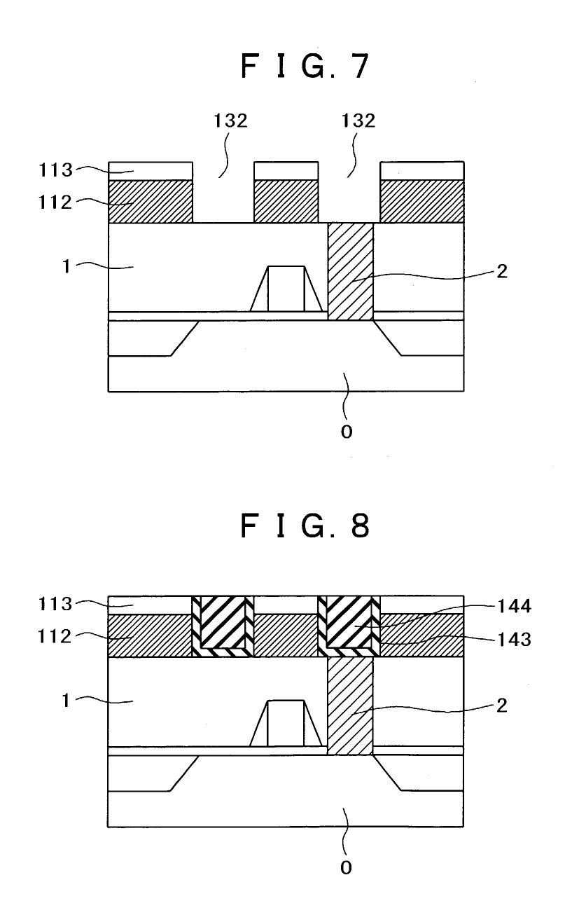

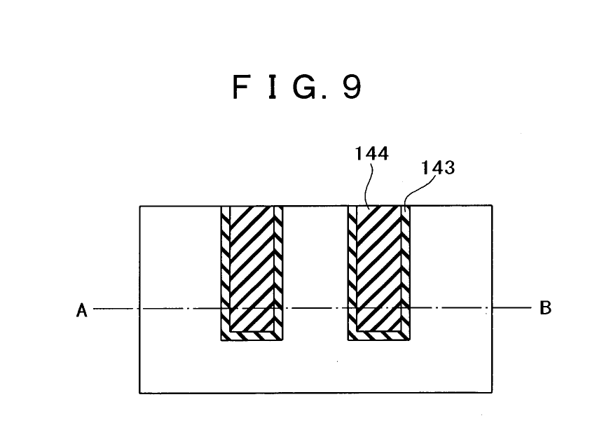

At first, a pre-metal insulating film 1 and a contact 2 were formed on a semiconductor substrate 0 formed with a transistors (FIG. 1 and FIG. 2). Then, an organosiloxane insulating film 112 with relative dielectric constant of 2.9 of 250 nm thickness and a silicon oxide film 113 of 80 nm thickness were formed by a plasma CVD method, and an aluminum oxide film 121 of 30 nm thickness was formed by a reactive sputtering method. Further, an anti-reflection coating 122 and an ArF resist 123 were formed and a lower layer wiring pattern 132 was formed by ArF lithography (FIG. 3). The antireflection coating 122 and the aluminum oxide 121 were patterned by using the resist 123 as a mask (FIG. 4). For the patterning of aluminum oxide, dry etching by a gas mixture of BCl₃ and Ar was used. The shape of the ArF resist was less deteriorated. Recess of the silicon oxide 113 by over etching was 15 nm or less and the underlying organosiloxane insulating film 112 was not exposed. Ashing was applied by oxygen plasma to remove the anti-reflection coating 122 and the ArF resist 123 (FIG. 5). Silicon oxide 113 and the organosiloxane insulating film 112 were patterned using the aluminum oxide 121 as a hard mask (FIG. 6). A gas mixture of CHF₃ and N₂ was used for etching. The selectivity between the organosiloxane insulating film 112 and the aluminum oxide 121 was 20. Further, post cleaning was conducted using a commercially available acidic cleaning solution containing NH₄F to dissolve and remove the aluminum oxide 121 together with etching residues (FIG. 7). The removing rate of the aluminum oxide 121 by the cleaning solution was 8 nm/min. Then, a barrier metal 143 and a Cu 144 were formed in the pattern by a damascene method comprising a directional sputtering method, a plating method and a CMP method in combination to form underlayer wirings (FIG. 8). FIG. 9 shows the upper plan view in this state. A cross sectional view taken along A-B corresponds to FIG. 8.

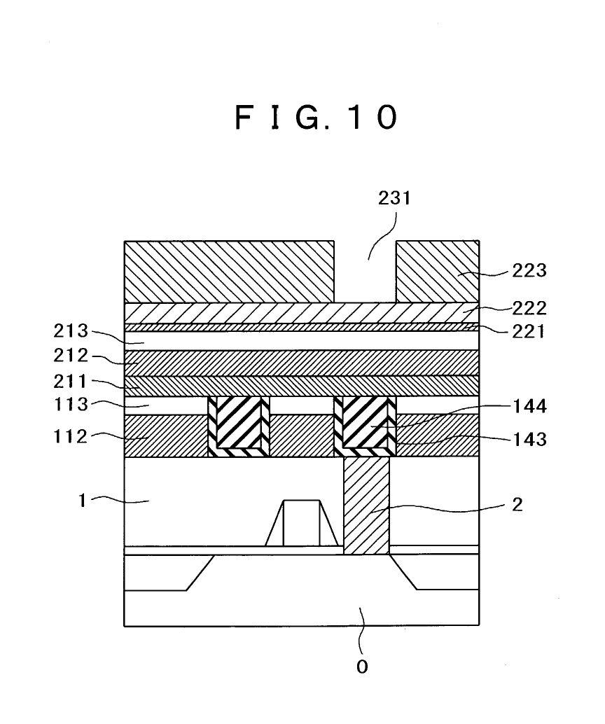

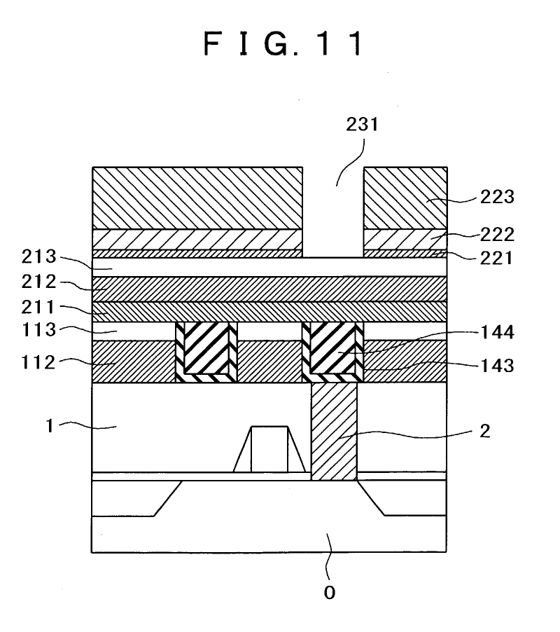

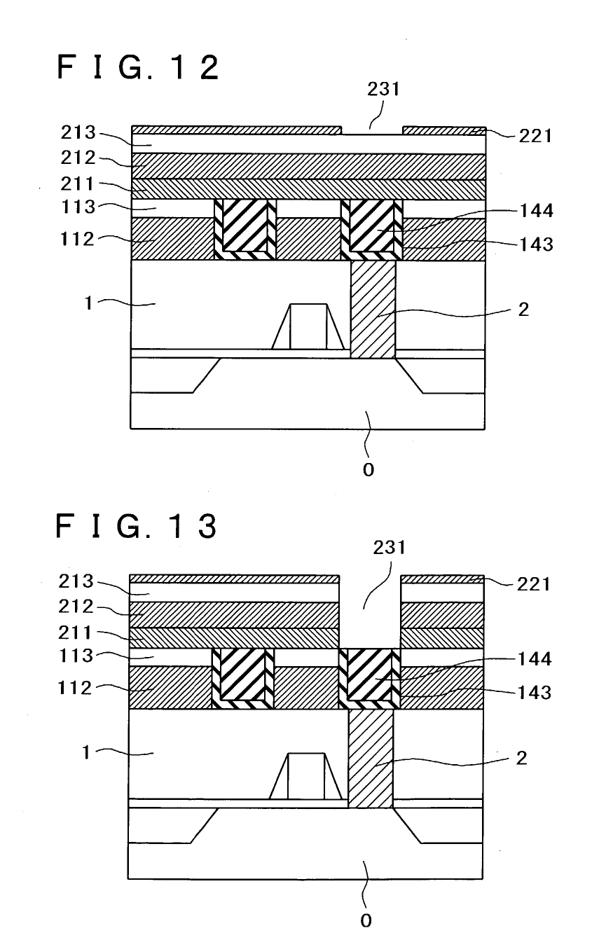

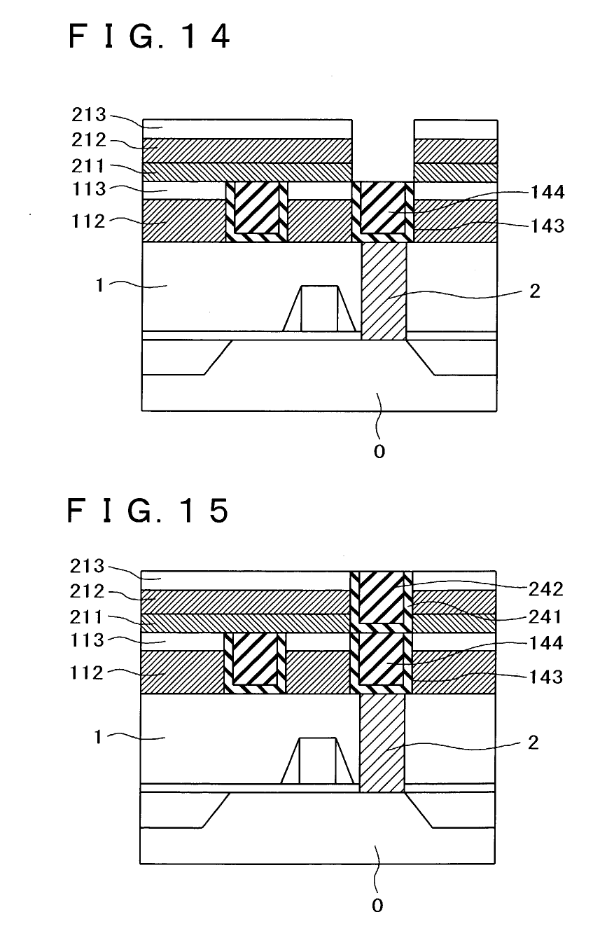

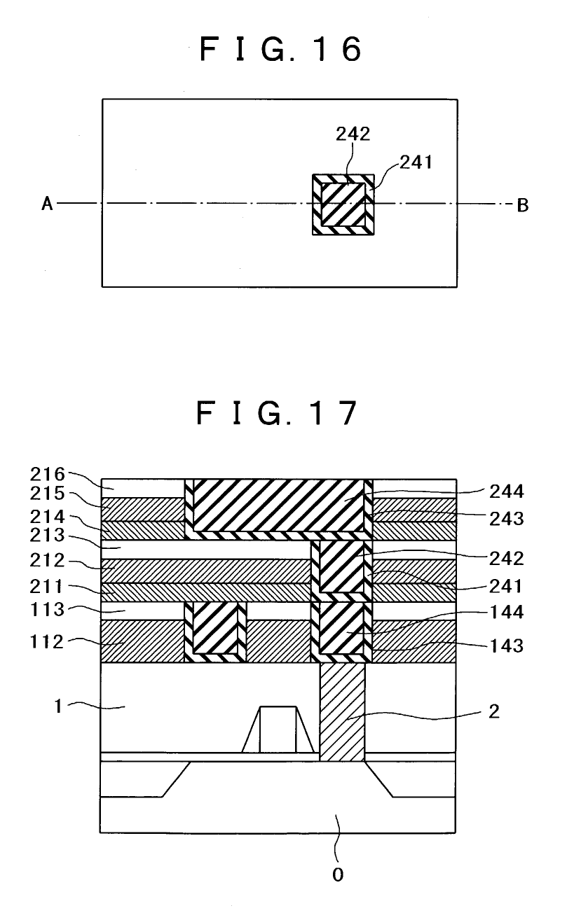

Further, a silicon carbonitride 211 of 20 nm thickness as a barrier insulating film, an organosiloxane insulating film 212 of 250 nm thickness and a silicon oxide film 213 of 80 nm thickness were formed by a plasma CVD method, and an aluminum oxide film 221 of 30 nm thickness was formed by a reactive sputtering method (FIG. 10). By the same method as described above, a via hole pattern 231 was formed, and a barrier metal 241 and a Cu 242 were formed in the pattern by a damascene method for via connection (FIG. 11 to FIG. 15). FIG. 16 shows an upper plan view in this state. The cross sectional view taken along A-B corresponds to FIG. 15.

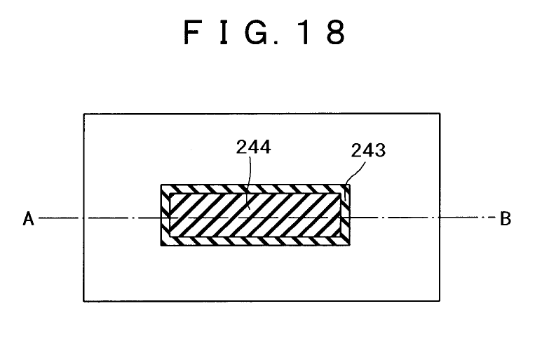

Further, a silicon carbonitride 211, 214 of 20 nm thickness as a barrier insulating film, an organosiloxane insulating film 215 of 250 nm thickness and a silicon oxide film 216 of 80 nm thickness were formed by a plasma CVD method, and an aluminum oxide film of 30 nm thickness was formed by a reactive sputtering method. An upper layer wiring pattern was formed by the same method as described above, and a barrier metal 243 and Cu 244 were formed in the pattern by a damascene method to form upper layer wirings (FIG. 17). FIG. 18 shows an upper plan view in this state. A cross sectional view taken along A-B corresponds to FIG. 17.

When electric characteristics between adjacent wirings were evaluated, increase in the dielectric constant or degradation in the pressure proof due to damages of the organosiloxane insulating film were not observed.

In this embodiment, 2-level wirings were formed trially again on the substrate while replacing the silicon carbonitride 214 for the barrier insulating film with silicon nitride, silicon oxynitride and silicon carbide and they could be formed with no troubles.

<Embodiment 2>

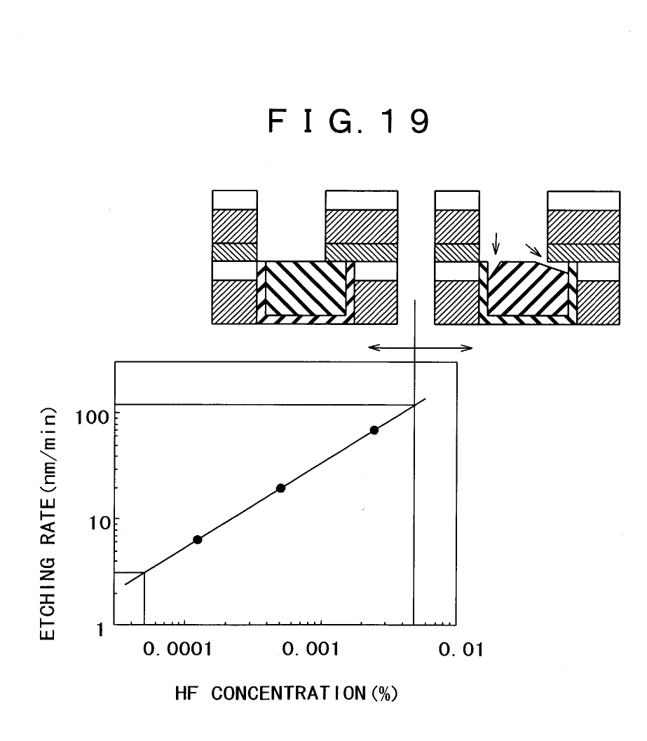

In Embodiment 1 described above, a diluted solution of hydrofluoric acid was used instead of the dissolving solution used for the removal of aluminum oxide. FIG. 19 shows a relation between the concentration of diluted hydrofluoric acid and a removing rate of aluminum oxide. Practical removing rate of 3 nm/min or more was obtained at a fluorine concentration of 0.0005% or more. However, when the fluorine concentration was higher than 0.5%, it resulted in problems that the surface of the underlying Cu was roughened and the interface between Cu and the barrier insulating film or the barrier metal was etched. Wirings applied with the diluted solution of hydrofluoric acid at a concentration of 0.0005% or more and 0.5% or less showed characteristics comparable with those of Embodiment 1. A diluted solution of hydrofluoric acid was applied instead of the dissolving solution used for removal of aluminum oxide. When electric characteristics between adjacent wirings of the thus formed wirings was evaluated, increase in the dielectric constant or increase in the leakage current due to the damages of the organosiloxane insulating film were not observed.

<Embodiment 3>

In Embodiment 1, the organosiloxane insulating film was changed for a porous organosiloxane insulating film with relative dielectric constant of 2.5 and 2-level wirings were manufactured trially in the same manner. In this case, a diluted solution of hydrofluoric acid at 0.005% concentration was applied. When electric characteristics between adjacent wirings of the thus formed wirings was evaluated, increase in the dielectric constant or increase in the leakage current due to the damages of the organosiloxane insulating film were not observed.

<Embodiment 4>

Cu multi-level wirings for a semiconductor device were prepared by a dual damascene method.

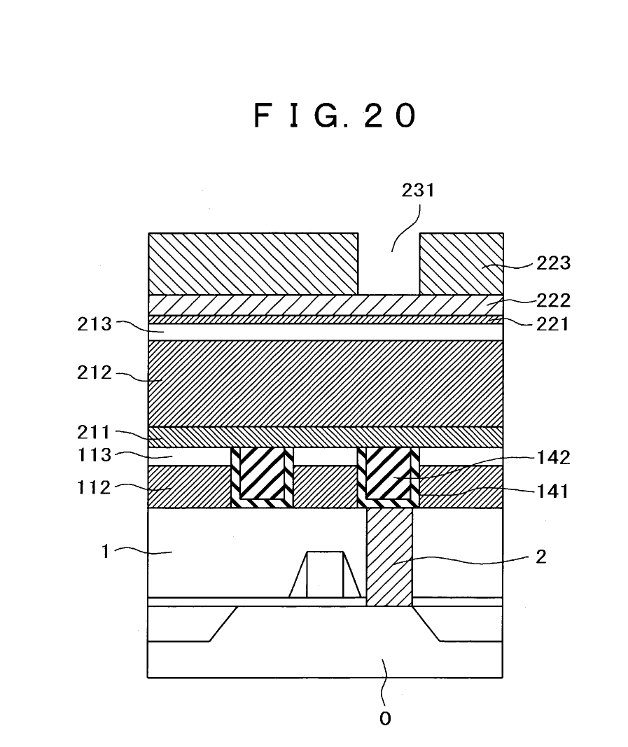

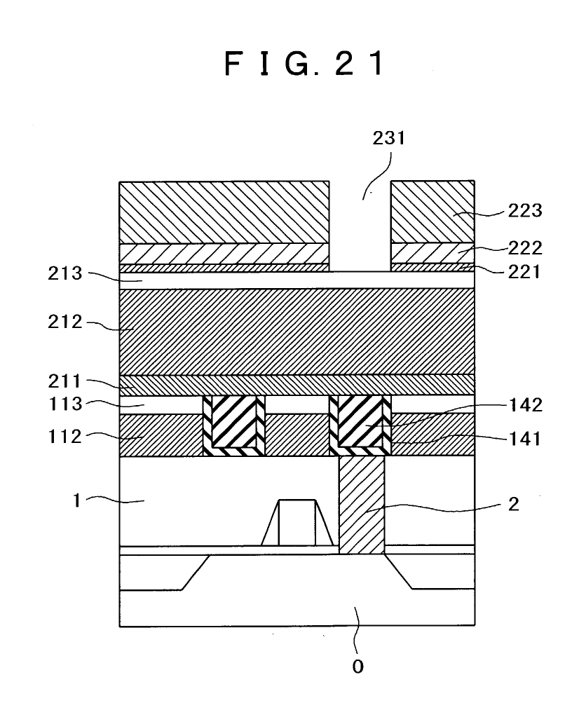

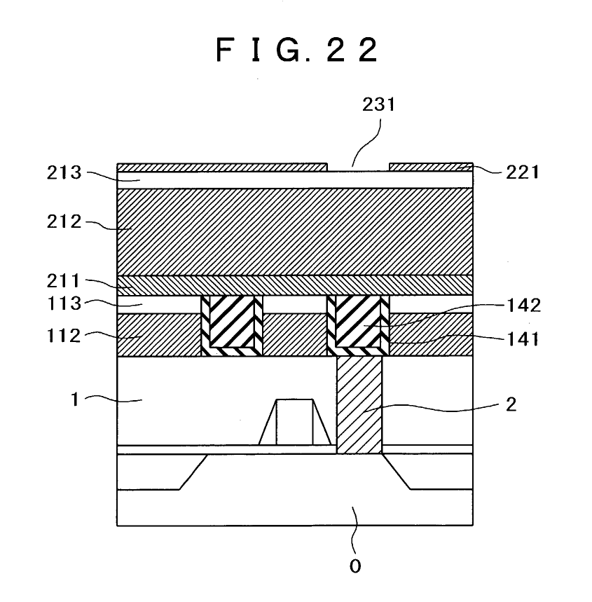

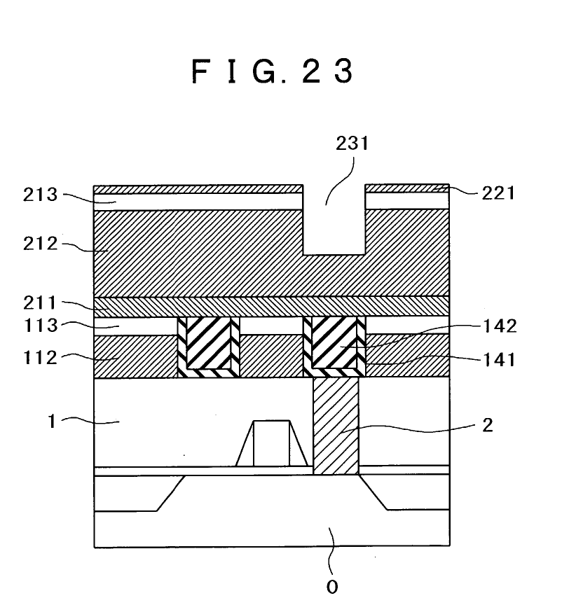

At first, a silicon carbonitride barrier insulating film 211 of 20 nm thickness, an organosiloxane insulating film 212 with relative dielectric constant of 2.9 of 500 nm thickness and a silicon oxide film 213 of 80 nm thickness were formed by a plasma CVD method, and an aluminum oxide film 211 of 30 nm thickness was formed by a reactive sputtering method. Further, an anti-reflection coating 222 and an ArF resist 223 were formed and a via hole pattern 231 was formed by ArF lithography (FIG. 20). The anti-reflection coating 222 and the aluminum oxide 221 were patterned by using the resist 223 as a mask (FIG. 21). For the patterning of aluminum oxide, dry etching by a gas mixture of BCl₃ and Ar was used. The shape of the ArF resist was less deteriorated. Recess of the silicon oxide 213 by over etching was 15 nm or less and the underlying organosiloxane insulation film 212 was not exposed. Ashing was applied by oxygen plasma to remove the antireflection coating 222 and the ArF resist 223 (FIG. 22). Silicon oxide 213 and a portion of the organosiloxane insulating film 212 were patterned by using the aluminum oxide 221 as a hard mask (FIG. 23). A gas mixture of CHF₃ and N₂ was used for etching. The selectivity between the organosiloxane insulating film 212 and the aluminum oxide 221 was 20.

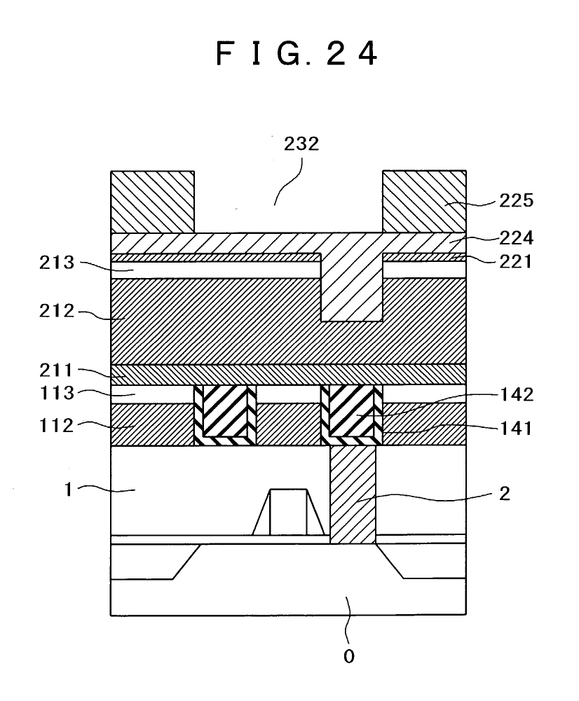

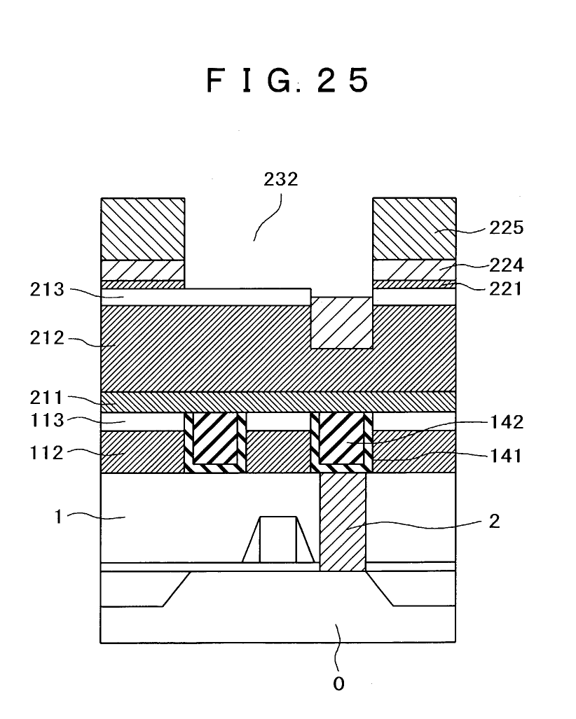

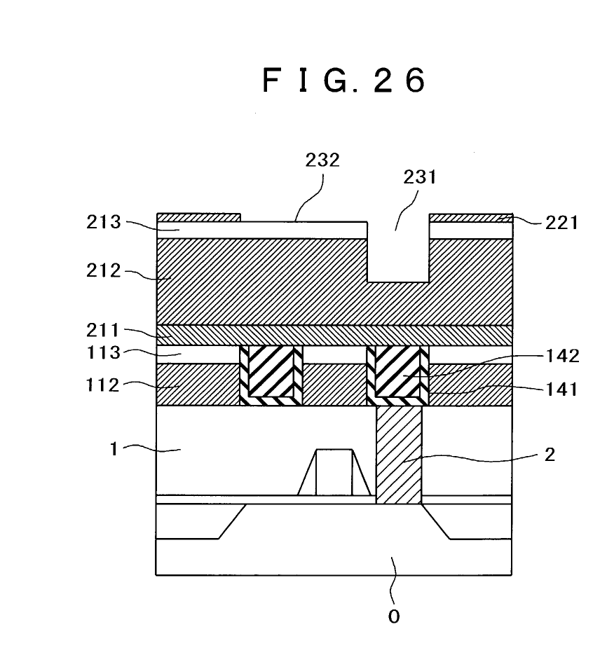

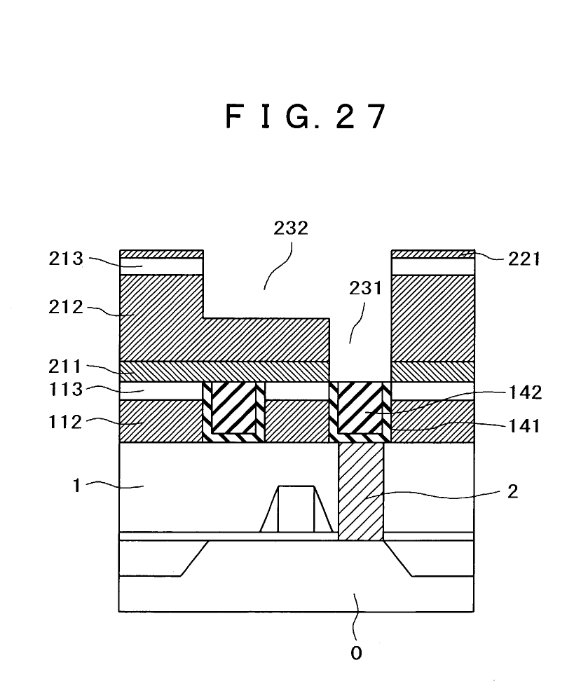

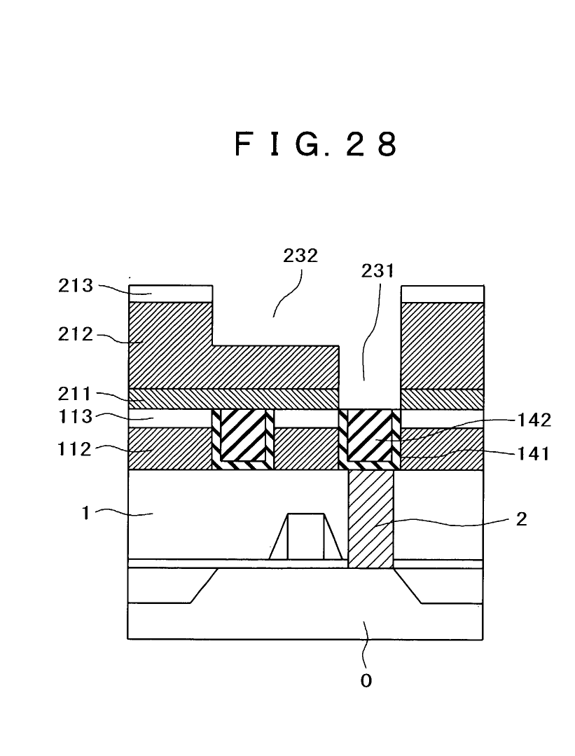

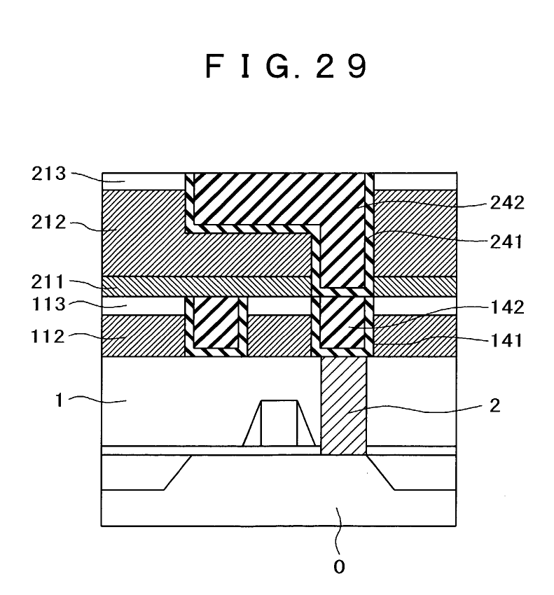

Then, an anti-reflection coating 224 and an ArF resist 225 were formed and an upper layer wiring pattern 232 was formed by ArF lithography (FIG. 24). The anti-reflection coating 224 and the aluminum oxide 221 were patterned using a resist 225 as a mask (FIG. 25). Further, ashing was applied to remove the anti-reflection coating 224 and the ArF resist 225 (FIG. 26). In the ashing, low pressure oxygen plasma at 10 mTorr were used so as to minimize damages to the organosiloxane insulating film 212. The silicon oxide 213, the organosiloxane insulating film 212 and the silicon carbonitride film 211 were patterned by using the aluminum oxide 221 as a hard mask (FIG. 27). A gas mixture of CHF₃ and N₂ was used for etching. The selectivity between the organosiloxane insulating film 212 and aluminum oxide 221 was 20. Further, post cleaning was conducted using a commercially available an acidic cleaning solution containing NH₄F to dissolve and remove aluminum oxide 221 together with etching residues (FIG. 28). The removing rate of aluminum oxide 221 by the cleaning solution was 8 nm/min. Then, barrier metal 241 and Cu 242 were formed in the pattern by a damascene method comprising a directional sputtering method, a plating method and a CMP method in combination to form upper layer wirings and via connections (FIG. 29).

When electric characteristics between adjacent wirings were evaluated, increase in the dielectric constant or increase in leakage current due to damages of the organosiloxane insulating film were not observed.

In this embodiment, 2-level wirings were formed trially again on the substrate while replacing the silicon carbonitride 211 for the barrier insulating film with silicon nitride, silicon oxynitride and silicon carbide and they could be formed with no troubles.

<Embodiment 5>

Cu multi-level wirings for a semiconductor device were prepared by a dual damascene method.

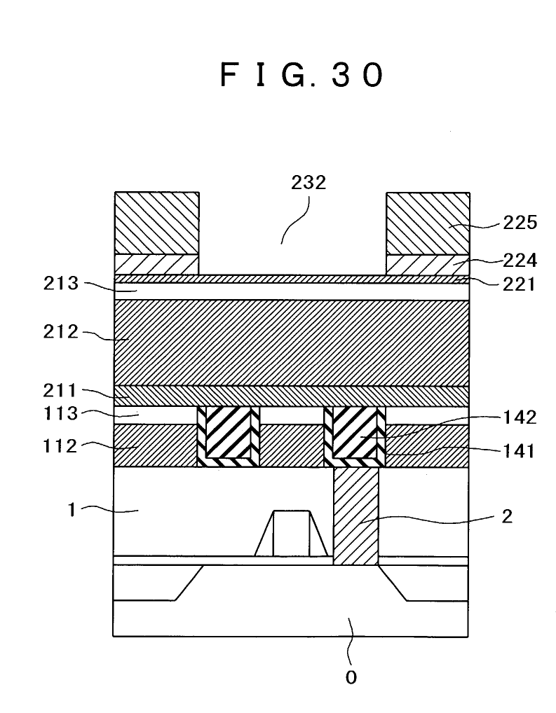

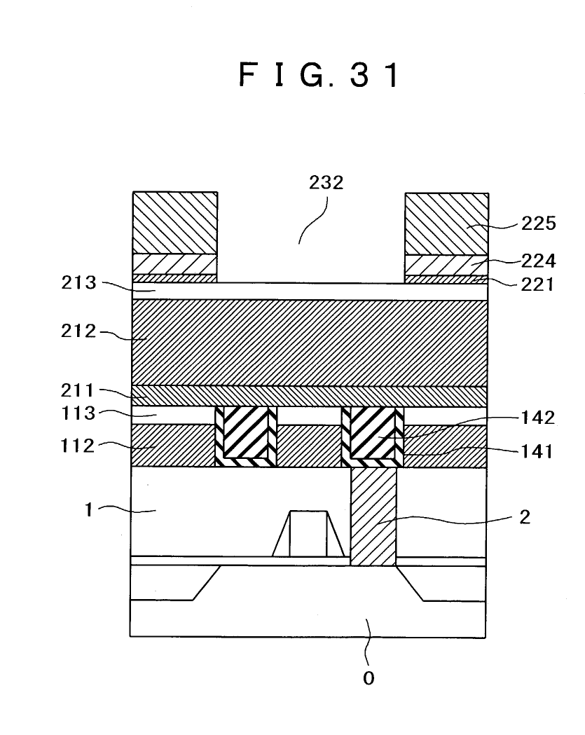

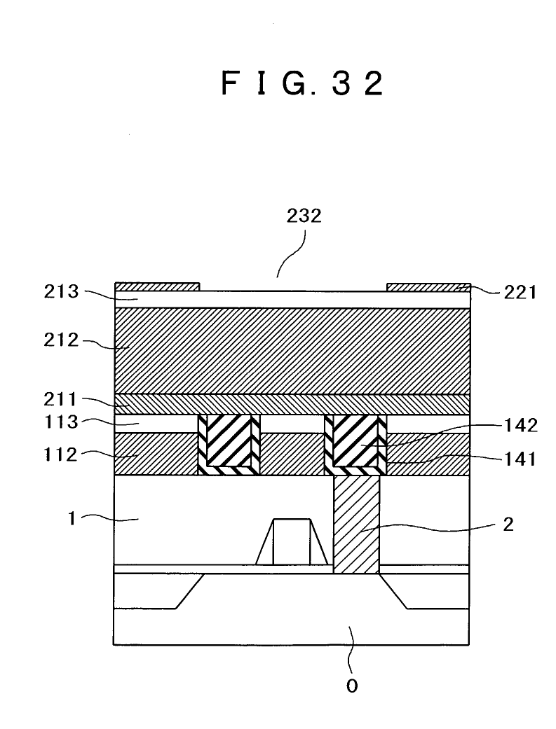

At first, a silicon carbonitride barrier insulating film 211 of 20 nm thickness, an organosiloxane insulating film 212 with relative dielectric constant of 2.9 of 500 nm thickness and a silicon oxide film 213 of 80 nm thickness were formed by a plasma CVD method, and an aluminum oxide film 221 of 30 nm thickness was formed by a reactive sputtering method. Further, an anti-reflection coating 224 and an ArF resist 225 were formed and an upper layer pattern 232 was formed by ArF lithography (FIG. 30). The anti-reflection coating 224 and the aluminum oxide 221 were patterned by using the resist 225 as a mask (FIG. 31). For the patterning of aluminum oxide, dry etching by a gas mixture of BCl₃ and Ar was used. The shape of the ArF resist was less deteriorated. Recess of the silicon oxide 213 by over etching was 15 nm or less and the underlying organosiloxane insulating film 212 was not exposed. Ashing was applied by oxygen plasma to remove the antireflection coating 224 and the ArF resist 225 (FIG. 32).

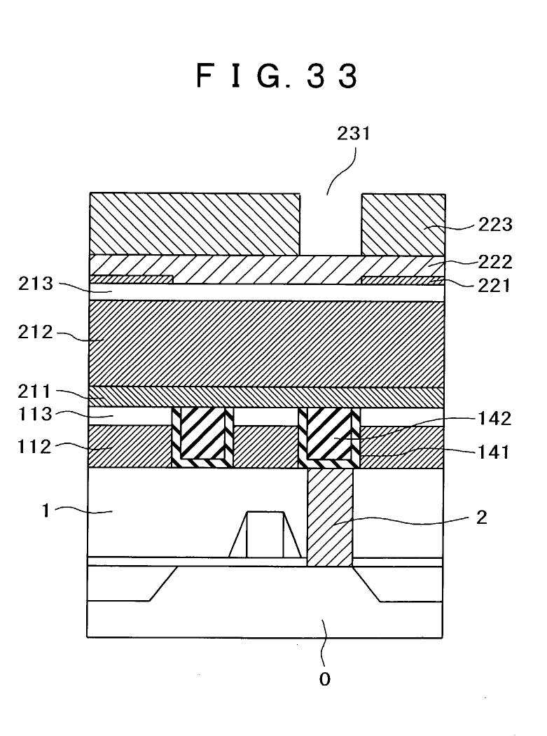

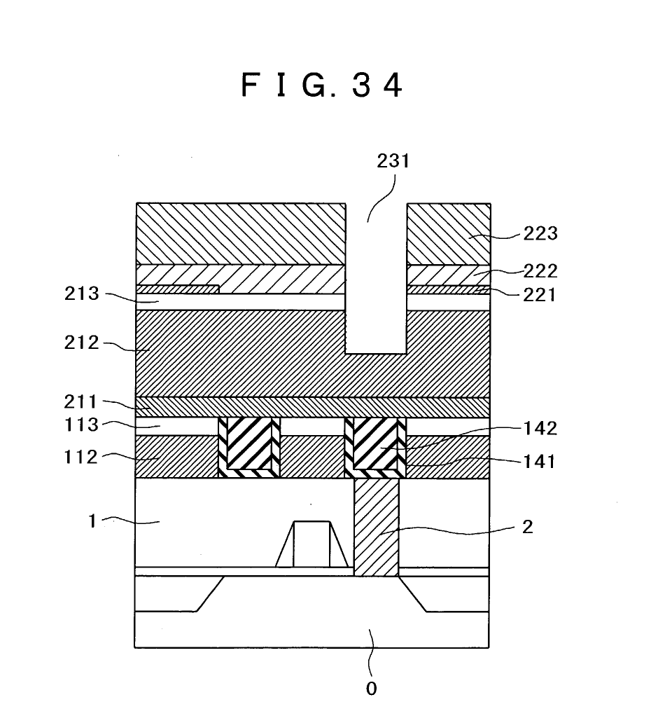

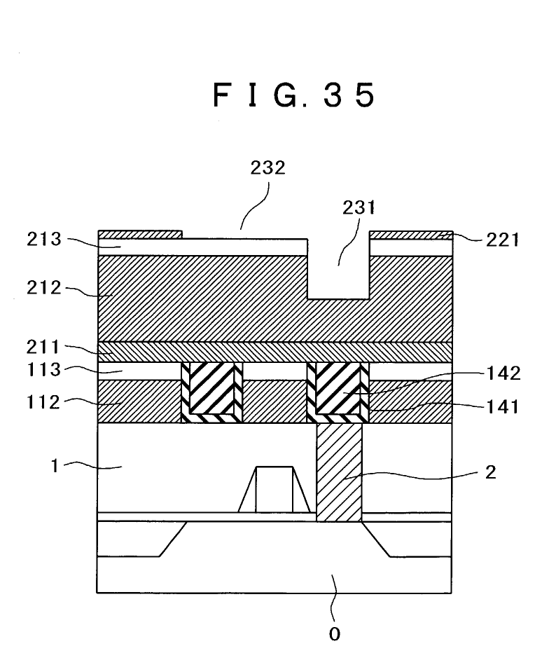

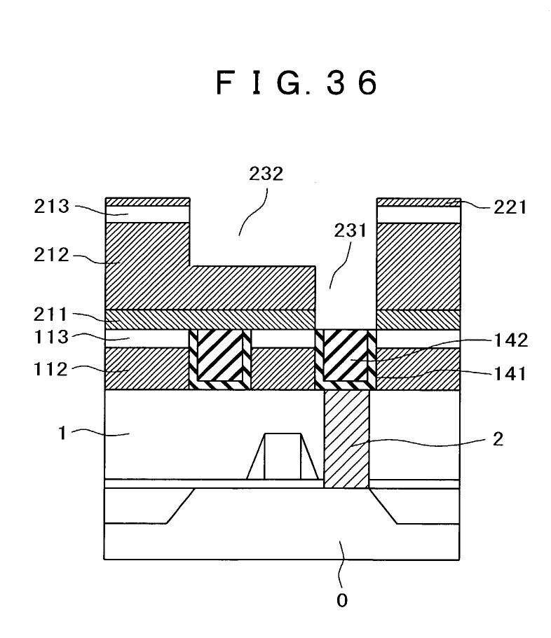

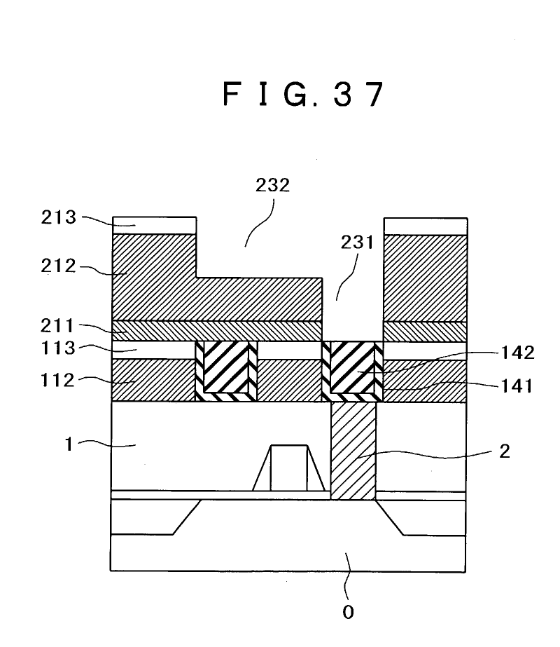

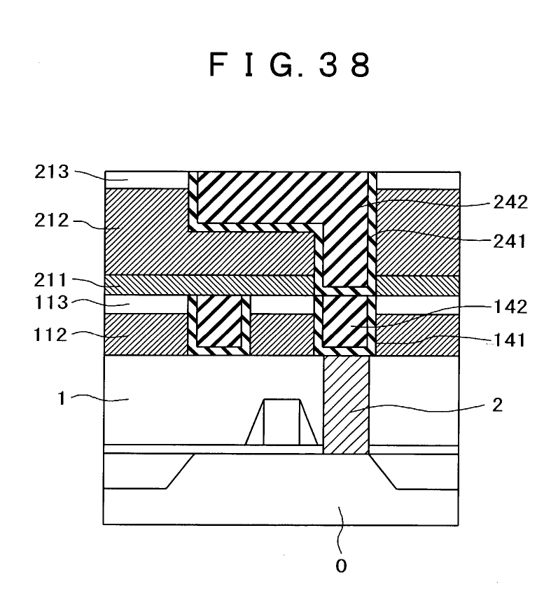

Then, an anti-reflection coating 224 and an ArF resist 223 were formed and a via hole pattern 231 was formed by ArF lithography (FIG. 33). The anti-reflection coating 222, silicon oxide 213 and a portion of the organosiloxane 212 were patterned using a resist 225 as a mask (FIG. 34. Further, ashing was applied to remove the anti-reflection coating 222 and the ArF resist 223 (FIG. 35). In the ashing, low pressure oxygen plasma at 10 mTorr was used so as to minimize damages to the organosiloxane insulating film 212. The silicon oxide 213, the organosiloxane insulating film 212 and the silicon carbonitride film 211 were patterned by using the aluminum oxide 221 as a hard mask (FIG. 36). A gas mixture of CHF₃ and N₂ was used for etching. The selectivity of the organosiloxane insulating film 212 to the aluminum oxide 221 was 20. Further, post cleaning was conducted using a commercially available acidic cleaning solution containing NH₄F to dissolve and remove the aluminum oxide film 221 together with etching residues (FIG. 37). The removing rate of the aluminum oxide 221 by the cleaning solution was 8 nm/min. Then, a barrier metal 241 and a Cu 242 were formed in the pattern by a damascene method comprising a directional sputtering method, a plating method and a CMP method in combination to form upper layer wirings and via connections (FIG. 38).

When electric characteristics between adjacent wirings were evaluated, increase in the dielectric constant or increase in leakage current due to damages of the organosiloxane insulating film were not observed.

In this embodiment, 2-level wirings were formed trially again on the substrate while replacing the silicon carbonitride 211 for the barrier insulating film with silicon nitride, silicon oxynitride and silicon carbide and they could be formed with no troubles.

Further, in this embodiment, 2-level wirings were manufactured trially in the same manner while changing the organosiloxane insulating film 212 to a porous organosiloxane insulating film with relative dielectric constant of 2.5. In this case, a diluted solution of at 0.005% hydrofluoric acid was used. Further, subsequent to FIG. 34, etching was conducted by using a gas mixture of CF₄ and Ar instead of ashing. Under the conditions, the etching selectivity ratio of the porous organosiloxane insulating film to the aluminum oxide was 50. Further, the etching selectivity of the resist, the anti-reflection coating and the silicon oxide film to the porous organosiloxane insulating film was 0.5. When the conditions were adopted, removal of the resist 223 and the anti-reflection coating 222, and patterning of the silicon oxide film 213 and the porous organosiloxane insulating film 212 could be conducted simultaneously using the aluminum oxide 221 as a hard mask to directly reach from the state of FIG. 34 to FIG. 36. Since the ashing was not used, increase in the dielectric constant and increase in leakage current due to damages to the porous organosiloxane insulating film were not observed.

This invention can provide a highly accurate hole and trench fabrication process for an organosiloxane insulating film without giving damages by asher treatment to the organosiloxane insulating film and causing no problems of shape deterioration and obstacles and Cu multi-level wirings can be formed by a single damascene method or a dual damascene method.

<Embodiment 6>

Cu multi-level wirings for a semiconductor device were prepared by a dual damascene method.

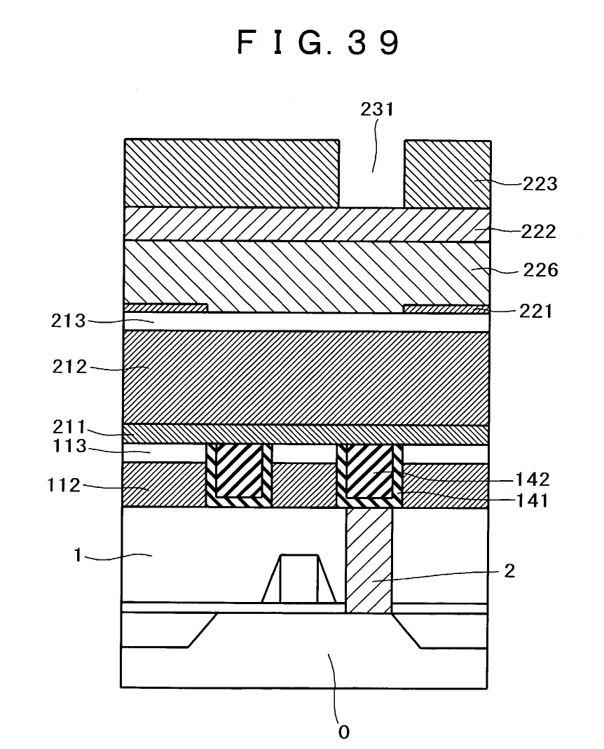

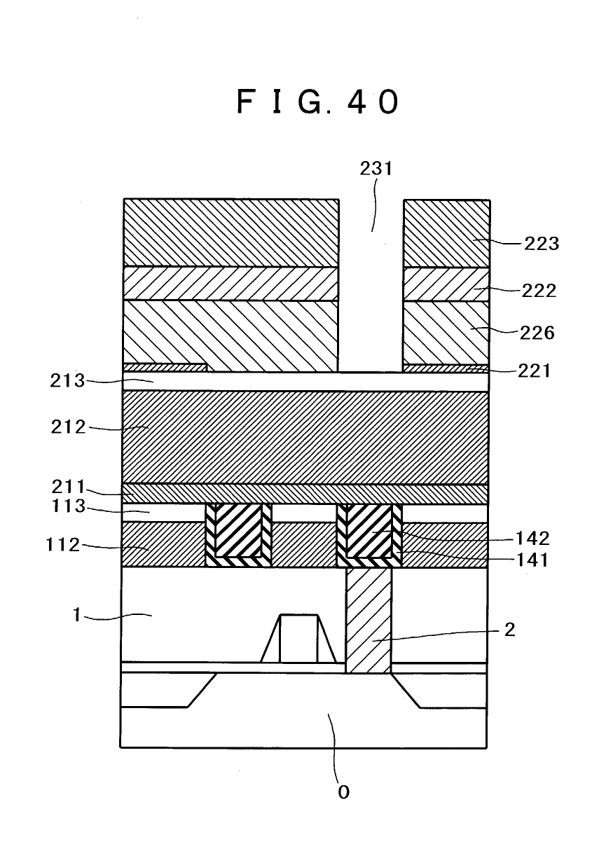

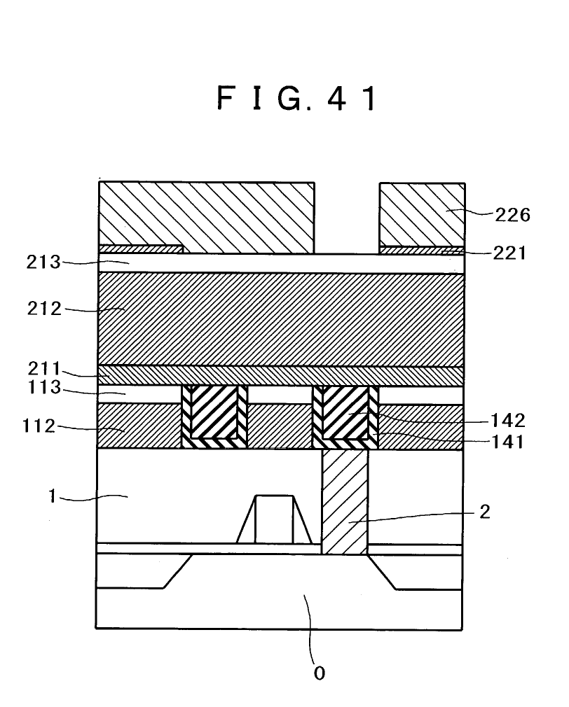

At first, the structure shown in FIG. 32 was prepared in the same way wa the embodiment 5. Next, hydrogen-siloxane-type SOG (spin-on glass, Tokyo Ohka OCD-type 12) was coated as a sacrificial film 226. Then, an anti-refraction coating 222 and ArF resist 223 was formed and a via hole pattern 231 was formed by ArF lithography (FIG. 39). The anti-reflection coating 222 and the sacrificial film 226 were patterned by using the resist 223 as a mask (FIG. 40). Then, the resist 223 and the anti-reflection coating 222 were removed by ashing (FIG. 41). For the ashing, low-pressure oxygen plasma at 10 mTorr was employed to minimize the shrinkage of the sacrificial film 226, so the size of via hole pattern 231 was kept to be the same.

Then, the silicon oxide 213, the organosiloxane insulating film 212 and the silicon-carbonitride film 211 were patterned by using the sacrificial film 226 and the aluminum oxide 221 as hard masks (FIG. 36). A gas mixture of CHF₃ and N₂ was used for etching. The selectivity of the organosiloxane insulating film 212 to the sacrificial film 226 was 1 and that of the organosiloxane insulating film 212 to the aluminum oxide 221 was 20. Further, post cleaning was conducted using a commercially available acidic cleaning solution containing NH4F to dissolve and remove aluminum oxide 221 together with etching residues (FIG. 37). The removing rate of aluminum oxide 221 by the cleaning solution was 8 nm/min. Then, barrier metal 241 and Cu 242 were formed in the pattern by a damascene method comprising a directional sputtering method, a plating method, and a CMP method in combination, to from upper and layer wirings and via-connections (FIG. 38).

When electrical characteristics between adjacent wirings were evaluated, increase in the dielectric constant or increase in leakage current due to damages of the organosiloxane insulating film were not observed, because the organosiloxane insulating film were not exposed during ashing.

In this embodiment, 2-level wirings were formed trially again on the substrate while replacing the silicon carbonitride 214 for the barrier insulating film with silicon nitride silicon oxynitride, and silicon carbide, and they were formed with no troubles.

In this embodiment, 2-level wirings were formed trially again on the substrate while replacing the organosiloxane insulating film 212 with porous organosiloxane insulating film with dielectric constant of 2.5. When electrical characteristics between adjacent wirings were evaluated, increase in the dielectric constant or increase in leakage current due to damages of the porous organosiloxane insulating film were not observed, because the porous organosiloxane insulating film were not exposed during ashing.

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than a restrictive sense.

What is claimed is:

1. A method of manufacturing a semiconductor device, the method comprising:
forming a first insulating film;
forming a second insulating film on the first insulating film;
forming an inorganic thin film soluble to a dissolving solution on the second insulating film;
forming a resist pattern on the inorganic thin film;
transferring the resist pattern to the inorganic thin film by dry etching;
removing the resist pattern;
transferring the pattern of the inorganic thin film to the first insulating film and the second insulating film by dry etching; and
removing the inorganic thin film by dissolving into a solution.

2. A method of manufacturing a semiconductor device, the method comprising:
forming a first insulating film;
forming a second insulating film on the first insulating film;
forming an inorganic thin film on the second insulating film;
forming a first resist pattern on the inorganic thin film;
transferring the first resist pattern to the inorganic thin film by dry etching;
removing the first resist pattern;
forming a second resist pattern on the inorganic thin film;
transferring the second resist pattern at least to the second insulating film by dry etching; and
removing the inorganic thin film by dissolving into a solution.

3. The method of claim 2, wherein the first resist pattern is a wiring pattern and the second resist pattern is a via hole pattern.

4. The method of claim 2, wherein the first resist pattern is a via hole pattern and the second resist pattern is a wiring pattern.

5. The method of claim 1, wherein the inorganic thin film comprises a metal oxide or metal oxynitride.

6. The method of claim 1, wherein the inorganic thin film is aluminum oxide or aluminum oxynitride.

7. The method of claim 1, wherein the inorganic thin film is formed by a sputtering method or a reactive sputtering method.

8. The method of claim 1, wherein the dissolving solution contains at least fluorine.

9. The method of claim 8, wherein fluorine concentration in the dissolving solution is between about 0.0005% and about 0.5%.

10. The method of claim 1, wherein the second insulating film comprises one of silicon oxide, silicon nitride, silicon oxynitride, silicon carbide and silicon carbonitride.

11. The method of claim 1, wherein the second insulating film is a laminate film comprising silicon oxide formed on silicon carbide.

12. The method of claim 1, wherein the first insulating film is an organosiloxane insulating film.

13. The method of claim 1, wherein the first insulating film is a laminate film prepared by forming an organosiloxane insulating film on one of silicon nitride, silicon oxynitride, silicon carbide and silicon carbonitride.

14. The method of claim 1, wherein the step of transferring the resist to the inorganic thin film comprises using a dry etching with a gas containing at least chlorine.

15. The method of claim 1, wherein a dry etching gas in the step of transferring the resist pattern to the inorganic thin film contains at least Cl₂ or BCl₃.

16. The method of claim 1, wherein the step of forming the resist pattern comprises using ArF lithography.

17. The method of claim 1, further comprising forming a metal film containing at least Cu.

18. A method of manufacturing a semiconductor device, the method comprising:
forming a first insulating film including one of silicon oxide, silicon nitride, silicon oxynitride, silicon carbide and silicon carbonitride on an organosiloxane insulating film;
forming an inorganic thin film including at least one of aluminum oxide and aluminum oxynitride on the first insulating film; and
removing a portion of the inorganic thin film without exposing the organosiloxane insulating film and thereby without exposing the first insulating film.

19. The method of claim 18, wherein the laminate film comprises silicon oxide and silicon carbide, and wherein the inorganic thin film includes aluminum and aluminum oxynitride on the first insulating film.

20. The method of claim 18, further comprising selectively removing one of aluminum oxide and aluminum oxynitride from a structure, wherein on the structure at least Cu is exposed by using a solution having a fluorine concentration of between about 0.0005% and about 0.5%.
